(19) United States
(12) Patent Application Publication
(10) Pub. No.: US 2015/0048514 A1
(43) Pub. Date: Feb. 19, 2015

(54) STACKED VIA STRUCTURES AND METHODS OF FABRICATION

(71) Applicant: QUALCOMM MEMS Technologies, Inc., San Diego, CA (US)

(72) Inventors: Hairong Tang, San Jose, CA (US); Yaoling Pan, San Diego, CA (US); Tsengyou Syau, San Jose, CA (US)

(73) Assignee: QUALCOMM MEMS Technologies, Inc., San Diego, CA (US)

(21) Appl. No.: 13/967,243

(22) Filed: Aug. 14, 2013

(51) Int. Cl. H01L 23/48; H01L 21/768

(52) U.S. Cl. CPC H01L 23/481; H01L 21/768
USPC 257/774; 438/638

(57) ABSTRACT

This disclosure provides systems, methods and apparatus for a stacked via having a top via structure and a bottom via structure. In one aspect, the bottom via structure includes a bottom dielectric layer and a bottom via extending through the bottom dielectric layer. The bottom via includes a bottom metal formed on the bottom dielectric layer, where the bottom via is substantially filled by a dielectric material. The top via structure includes a top dielectric layer over the bottom metal and a top via extending to a top plane of the bottom via in the top dielectric layer. The top via includes a top metal formed on the top dielectric layer, where the top metal is in electrical contact with the bottom metal at a peripheral area of the bottom via structure.

### TECHNICAL FIELD

This disclosure relates to via structures and more particularly to via structures for electromechanical systems (EMS) devices.

### DESCRIPTION OF THE RELATED TECHNOLOGY

Electromechanical systems (EMS) include devices having electrical and mechanical elements, actuators, transducers, sensors, optical components such as mirrors and optical films, and electronics. EMS devices or elements can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

Vias and conductive traces may be used to electrically connect EMS devices to one another or to other components. For example, vias and conductive traces may allow electrical connections between different layers of materials that are included in EMS devices on a substrate.

### SUMMARY

The systems, methods and devices of this disclosure each have several innovative aspects, no single one of which is solely responsible for the desirable attributes disclosed herein.

One innovative aspect of the subject matter described in this disclosure can be implemented in an apparatus including a bottom via structure and a top via structure over the bottom via structure. The bottom via structure includes a bottom dielectric layer and a bottom via extending through the bottom dielectric layer and including a bottom metal formed on the bottom dielectric layer and along one or more sidewalls and a bottom plane of the bottom via, where the bottom via is substantially filled by a dielectric material. The top via structure includes a top dielectric layer over the bottom metal and a top via extending to a top plane of the bottom via in the top dielectric layer and including a top metal formed on the top dielectric layer and along one or more sidewalls and a bottom plane of the top via, where the top metal is in electrical contact with the bottom metal at a peripheral area of the bottom via structure.

In some implementations, a width of the top via can be greater than a width of the bottom via. In some implementations, central portions of the top and bottom metals are separated by the dielectric material. A part of the dielectric material can be part of the top dielectric layer. In some implementations, at least one of a depth or a width of each of the top via and the bottom via can be between about 0.1 μm and about 10 μm. In some implementations, the apparatus can be part of an EMS apparatus. The EMS apparatus can be part of a pixel array. In some implementations, the apparatus can include a metal contact in electrical communication with the bottom metal, where the metal contact is in electrical communication with one or more of an EMS device and a thin film transistor (TFT) device.

Another innovative aspect of the subject matter described in this disclosure can be implemented in a method providing a substrate and a metal contact on the surface of the substrate, depositing a bottom dielectric layer over the metal contact, forming a bottom via hole extending through the bottom dielectric layer to the metal contact, depositing a bottom metal on the bottom dielectric layer and along one or more sidewalls and the bottom plane of the bottom via hole, forming a top dielectric layer over the bottom metal that substantially fills the bottom via hole, forming a top via hole extending at least partially through the top dielectric layer to the top surface of the bottom metal, and depositing a top metal on the top dielectric layer and along one or more sidewalls and a bottom plane of the top via hole.

In some implementations, the method can include etching at least partially the top dielectric layer after depositing the top dielectric layer over the bottom metal, and re-depositing the top dielectric layer over the bottom metal that substantially refills the bottom via hole. In some implementations, etching at least partially the top dielectric layer includes etching only partially the top dielectric layer to provide one or more dielectric spacers along the one or more sidewalls of the bottom via hole. In some implementations, the method can include etching the bottom metal on the bottom dielectric layer to pattern the bottom metal. In some implementations, etching the bottom metal can occur before depositing the top dielectric layer over the bottom metal. In some implementations, depositing the top metal includes forming an electrical contact with the bottom metal at a peripheral area of the bottom metal. In some implementations, a width of the top via hole can be greater than a width of the bottom via hole.

Another innovative aspect of the subject matter described in this disclosure can be implemented in an apparatus including a metal contact, a bottom via structure over the metal contact, where the bottom via structure includes a bottom dielectric layer and a bottom via extending through the bottom dielectric layer and including a bottom metal formed on the bottom dielectric layer and along one or more sidewalls and a bottom plane of the bottom via, where the bottom metal is in electrical contact with the metal contact. The apparatus includes a top via structure over the bottom via structure, where the top via structure includes a top dielectric layer over the bottom metal, where the top dielectric layer substantially fills the bottom via, and a top via extending to a top plane of the bottom via in the top dielectric layer and including a top metal formed on the top dielectric layer and along one or more sidewalls and a bottom plane of the top via. The top metal can be in electrical contact with the bottom metal at a peripheral area of the bottom via structure. A width of the top via can be greater than a width of the bottom via, and central portions of the top and bottom metals can be separated by the top dielectric layer.

Details of one or more implementations of the subject matter described in this disclosure are set forth in the accompanying drawings and the description below. Although the examples provided in this disclosure are primarily described in terms of EMS and MEMS-based displays the concepts provided herein may apply to other types of displays such as liquid crystal displays (LCDs), organic light-emitting diode (“OLED”) displays, and field emission displays. Other features, aspects, and advantages will become apparent from the description, the drawings and the claims. Note that the relative dimensions of the following figures may not be drawn to scale.

### BRIEF DESCRIPTION OF THE DRAWINGS

FIG. 1 is an isometric view illustration depicting two adjacent interferometric modulator (IMOD) display elements in a series or array of display elements of an IMOD display device.

FIG. 2 is a system block diagram illustrating an electronic device incorporating an IMOD-based display including a three element by three element array of IMOD display elements.

FIGS. 3A-3E are cross-sectional illustrations of varying implementations of IMOD display elements.

FIGS. 4A and 4B show an example of a cross-sectional schematic illustration of a stacked via structure.

FIG. 5A shows an example of a top-down view of electrical interconnections in a display device.

FIG. 5B shows a magnified view of an example pixel region of the display device in FIG. 5A.

FIG. 6 shows a flow diagram illustrating an example method of manufacturing a stacked via structure.

FIGS. 7A-7G show cross-sectional example schematic illustrations of various stages of manufacturing a stacked via structure.

FIGS. 8A-8C show cross-sectional example schematic illustrations of various stages of forming a top dielectric layer with a hole as shown in FIG. 7E.

FIGS. 9A and 9B are system block diagrams illustrating a display device that includes a plurality of IMOD display elements.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that can be capable of displaying an image, whether in motion (such as video) or stationary (such as still images), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, clocks, calculators, television monitors, flat panel displays, electronic reading devices (e.g., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, as well as non-EMS applications), aesthetic structures (such as display of images on a piece of jewelry or clothing) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

Some implementations described herein relate to a stacked via structure. The stacked via structure can have a top via disposed on a top plane of a bottom via. A top metal in the top via can be in electrical contact with a bottom metal in the bottom via. In some implementations, the contact happens only at a peripheral area of the stacked via structure. In some implementations, a diameter of the top via is greater than a diameter of the bottom via. In some implementations, central portions of the top and bottom metals are separated by dielectric material. In some implementations, the stacked via structure is part of an EMS device. An example of an EMS device can be an interferometric modulator (IMOD) pixel.

Particular implementations of the subject matter described in this disclosure can be implemented to realize one or more of the following potential advantages. The stacked via structure typically has a small form factor compared to other conventional vias, such as staggered vias. The stacked via structure can reduce form factor by avoiding to vias at different layers that are horizontally staggered or offset from each other. A small form factor can be advantageous for in-pixel device applications, such as display and imaging sensors. A small form factor also can be advantageous for on-panel or in-chip integrated solutions for interconnections between pixels and electronic components, such as thin film transistors (TFTs), storage capacitors, or resistors. The stacked via structure also provides good vertical electrical interconnection and may be easier to fabricate than other via structures. In contrast to some conventional vias, such as direct vias, the stacked via structure can reduce complex fabrication processes resulting from different materials in different layers that may etch at different rates, that may require precise process control, and that may require different etchants. In some implementations, the stacked via structure can include a top via and a bottom via, with the top via having a wider diameter than the bottom via. This can reduce topography of the stacked via structure and provide more area to make electrical contact to the top via. In some implementations, electrical contact can be made in the peripheral areas rather than a central area of the stacked via structure, which may improve electrical interconnection. Furthermore, the stacked via structure provides for improved device integrity because a top metal may be conformally and continuously deposited more easily in a top via having a relatively small via depth-width aspect ratio.

An example of a suitable EMS or MEMS device or apparatus, to which the described implementations may apply, is a reflective display device. Reflective display devices can incorporate interferometric modulator (IMOD) display elements that can be implemented to selectively absorb and/or reflect light incident thereon using principles of optical interference. IMOD display elements can include a partial optical absorber, a reflector that is movable with respect to the absorber, and an optical resonant cavity defined between the absorber and the reflector. In some implementations, the reflector can be moved to two or more different positions, which can change the size of the optical resonant cavity and thereby affect the reflectance of the IMOD. The reflectance spectra of IMOD display elements can create fairly broad spectral bands that can be shifted across the visible wavelengths to generate different colors. The position of the spectral band can be adjusted by changing the thickness of the optical resonant cavity. One way of changing the optical resonant cavity is by changing the position of the reflector with respect to the absorber.

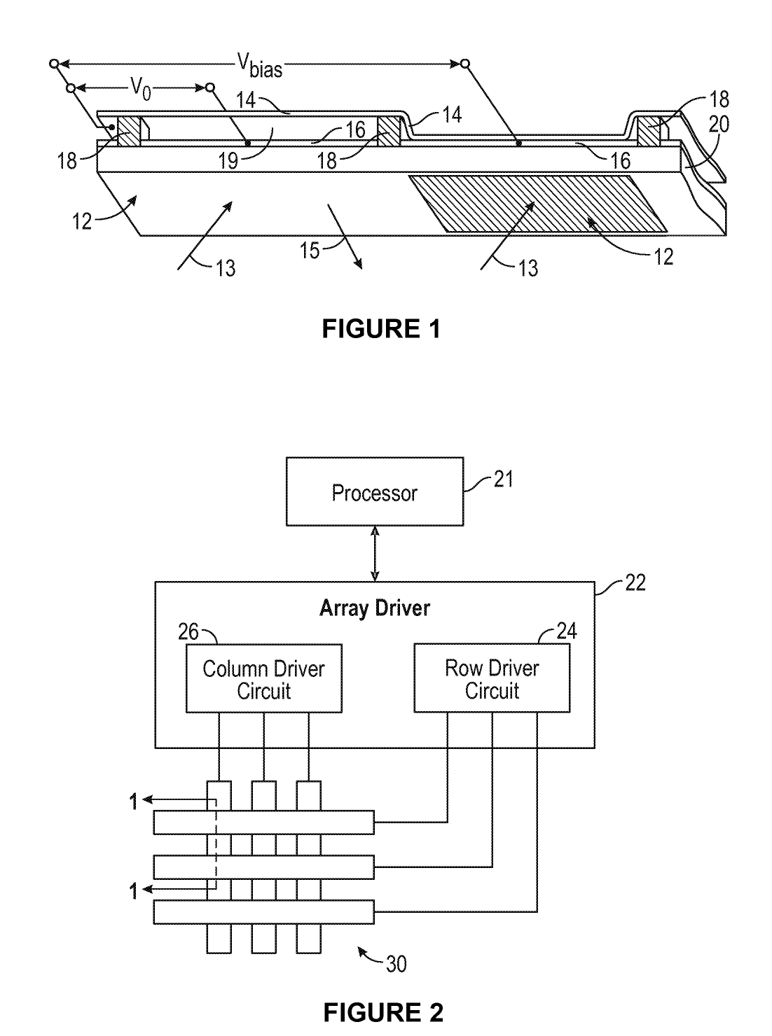

FIG. 1 is an isometric view illustration depicting two adjacent interferometric modulator (IMOD) display elements in a series or array of display elements of an IMOD display device. The IMOD display device includes one or more interferometric EMS, such as MEMS, display elements. In these devices, the interferometric MEMS display elements can be configured in either a bright or dark state. In the bright (“relaxed,” “open” or “on,” etc.) state, the display element reflects a large portion of incident visible light. Conversely, in the dark (“actuated,” “closed” or “off,” etc.) state, the display element reflects little incident visible light. MEMS display elements can be capable of reflecting predominantly at particular wavelengths of light allowing for a color display in addition to black and white. In some implementations, by using multiple display elements, different intensities of color primaries and shades of gray can be achieved.

The IMOD display device can include an array of IMOD display elements which may be arranged in rows and columns. Each display element in the array can include at least a pair of reflective and semi-reflective layers, such as a movable reflective layer (i.e., a movable layer, also referred to as a mechanical layer) and a fixed partially reflective layer (i.e., a stationary layer), positioned at a variable and controllable distance from each other to form an air gap (also referred to as an optical gap, cavity or optical resonant cavity). The movable reflective layer may be moved between at least two positions. For example, in a first position, i.e., a relaxed position, the movable reflective layer can be positioned at a distance from the fixed partially reflective layer. In a second position, i.e., an actuated position, the movable reflective layer can be positioned more closely to the partially reflective layer. Incident light that reflects from the two layers can interfere constructively and/or destructively depending on the position of the movable reflective layer and the wavelength(s) of the incident light, producing either an overall reflective or non-reflective state for each display element. In some implementations, the display element may be in a reflective state when unactuated, reflecting light within the visible spectrum, and may be in a dark state when actuated, absorbing and/or destructively interfering light within the visible range. In some other implementations, however, an IMOD display element may be in a dark state when unactuated, and in a reflective state when actuated. In some implementations, the introduction of an applied voltage can drive the display elements to change states. In some other implementations, an applied charge can drive the display elements to change states.

The depicted portion of the array in FIG. 1 includes two adjacent interferometric MEMS display elements in the form of IMOD display elements 12. In the display element 12 on the right (as illustrated), the movable reflective layer 14 is illustrated in an actuated position near, adjacent or touching the optical stack 16. The voltage V_{bias} applied across the display element 12 on the right is sufficient to move and also maintain the movable reflective layer 14 in the actuated position. In the display element 12 on the left (as illustrated), a movable reflective layer 14 is illustrated in a relaxed position at a distance (which may be predetermined based on design parameters) from an optical stack 16, which includes a partially reflective layer. The voltage V₀ applied across the display element 12 on the left is insufficient to cause actuation of the movable reflective layer 14 to an actuated position such as that of the display element 12 on the right.

In FIG. 1, the reflective properties of IMOD display elements 12 are generally illustrated with arrows indicating light 13 incident upon the IMOD display elements 12, and light 15 reflecting from the display element 12 on the left. Most of the light 13 incident upon the display elements 12 may be transmitted through the transparent substrate 20, toward the optical stack 16. A portion of the light incident upon the optical stack 16 may be transmitted through the partially reflective layer of the optical stack 16, and a portion will be reflected back through the transparent substrate 20. The portion of light 13 that is transmitted through the optical stack 16 may be reflected from the movable reflective layer 14, back toward (and through) the transparent substrate 20. Interference (constructive and/or destructive) between the light reflected from the partially reflective layer of the optical stack 16 and the light reflected from the movable reflective layer 14 will determine in part the intensity of wavelength(s) of light 15 reflected from the display element 12 on the viewing or substrate side of the device. In some implementations, the transparent substrate 20 can be a glass substrate (sometimes referred to as a glass plate or panel). The glass substrate may be or include, for example, a borosilicate glass, a soda lime glass, quartz, Pyrex, or other suitable glass material. In some implementations, the glass substrate may have a thickness of 0.3, 0.5 or 0.7 millimeters, although in some implementations the glass substrate can be thicker (such as tens of millimeters) or thinner (such as less than 0.3 millimeters). In some implementations, a non-glass substrate can be used, such as a polycarbonate, acrylic, polyethylene terephthalate (PET) or polyether ether ketone (PEEK) substrate. In such an implementation, the non-glass substrate will likely have a thickness of less than 0.7 millimeters, although the substrate may be thicker depending on the design considerations. In some implementations, a non-transparent substrate, such as a metal foil or stainless steel-based substrate can be used. For example, a reverse-IMOD-based display, which includes a fixed reflective layer and a movable layer which is partially transmissive and partially reflective, may be capable of being viewed from the opposite side of a substrate as the display elements 12 of FIG. 1 and may be supported by a non-transparent substrate.

The optical stack 16 can include a single layer or several layers. The layer(s) can include one or more of an electrode layer, a partially reflective and partially transmissive layer, and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals (e.g., chromium and/or molybdenum), semiconductors, and dielectrics. The partially reflective layer can be formed of one or more layers of materials, and each of the layers can be formed of a single material or a combination of materials. In some implementations, certain portions of the optical stack 16 can include a single semi-transparent thickness of metal or semiconductor which serves as both a partial optical absorber and electrical conductor, while different, electrically more conductive layers or portions (e.g., of the optical stack 16 or of other structures of the display element) can serve to bus signals between IMOD display elements. The optical stack 16 also can include one or more insulating or dielectric layers covering one or more conductive layers or an electrically conductive/partially absorptive layer.

In some implementations, at least some of the layer(s) of the optical stack 16 can be patterned into parallel strips, and may form row electrodes in a display device as described further below. As will be understood by one having ordinary skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of supports, such as the illustrated posts 18, and an intervening sacrificial material located between the posts 18. When the sacrificial material is etched away, a defined gap 19, or optical cavity, can be formed between the movable reflective layer 14 and the optical stack 16. In some implementations, the spacing between posts 18 may be approximately 1-1000 μm, while the gap 19 may be approximately less than 10,000 Angstroms (Å).

In some implementations, each IMOD display element, whether in the actuated or relaxed state, can be considered as a capacitor formed by the fixed and moving reflective layers. When no voltage is applied, the movable reflective layer 14 remains in a mechanically relaxed state, as illustrated by the display element 12 on the left in FIG. 1, with the gap 19 between the movable reflective layer 14 and optical stack 16. However, when a potential difference, i.e., a voltage, is applied to at least one of a selected row and column, the capacitor formed at the intersection of the row and column electrodes at the corresponding display element becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated display element 12 on the right in FIG. 1. The behavior can be the same regardless of the polarity of the applied potential difference. Though a series of display elements in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. In some implementations, the rows may be referred to as “common” lines and the columns may be referred to as “segment” lines, or vice versa. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 is a system block diagram illustrating an electronic device incorporating an IMOD-based display including a three element by three element array of IMOD display elements. The electronic device includes a processor 21 that may be capable of executing one or more software modules. In addition to executing an operating system, the processor 21 may be capable of executing one or more software applications, including a web browser, a telephone application, an email program, or any other software application.

The processor 21 can be capable of communicating with an array driver 22. The array driver 22 can include a row driver circuit 24 and a column driver circuit 26 that provide signals to, for example a display array or panel 30. The cross section of the IMOD display device illustrated in FIG. 1 is shown by the lines 1-1 in FIG. 2. Although FIG. 2 illustrates a 3×3 array of IMOD display elements for the sake of clarity, the display array 30 may contain a very large number of IMOD display elements, and may have a different number of IMOD display elements in rows than in columns, and vice versa.

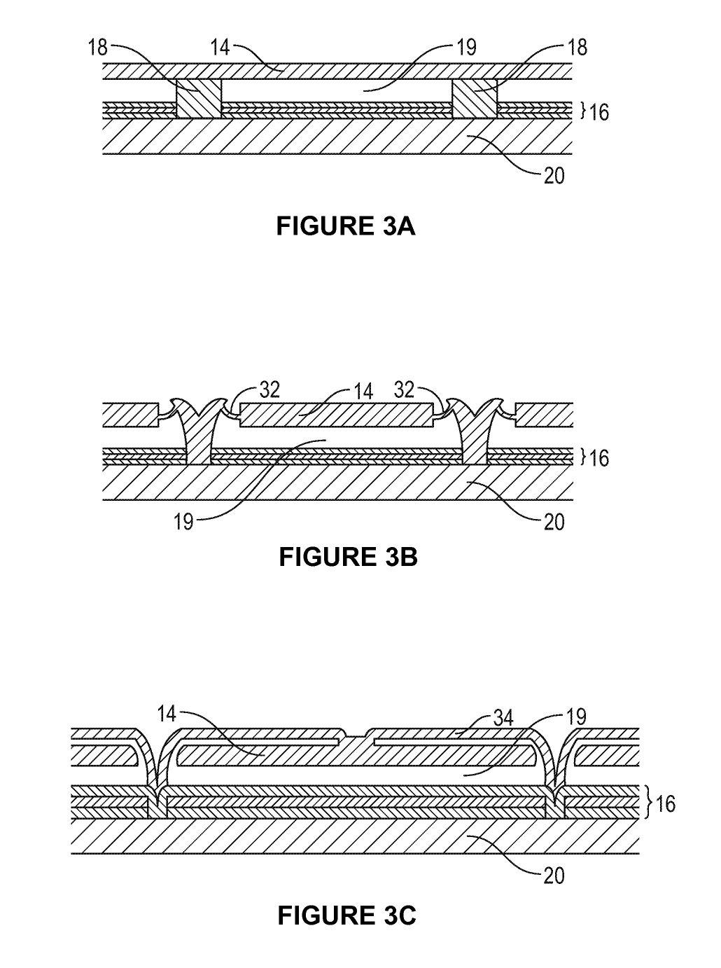

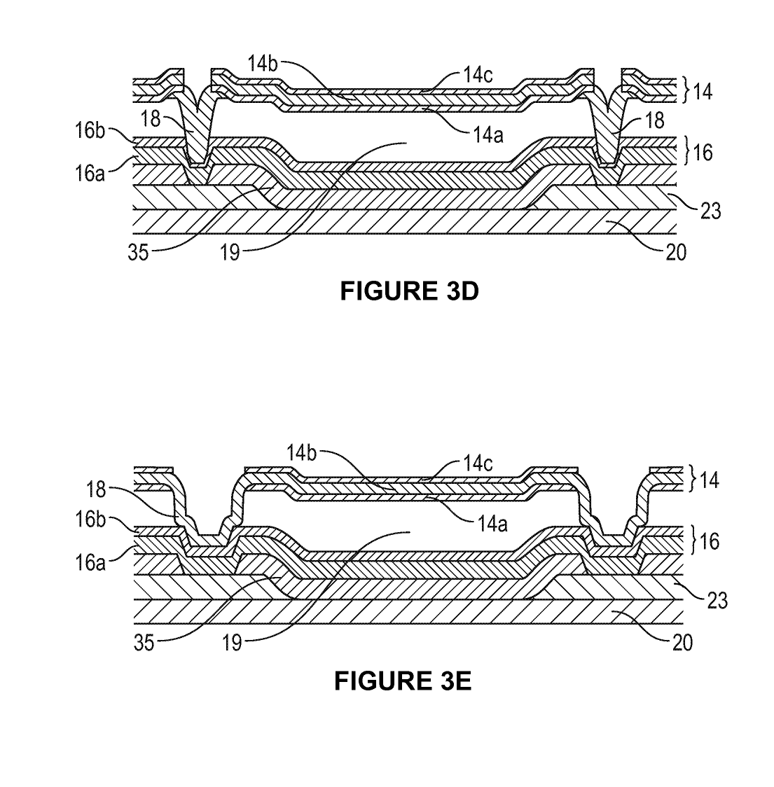

The details of the structure of IMOD displays and display elements may vary widely. FIGS. 3A-3E are cross-sectional illustrations of varying implementations of IMOD display elements. FIG. 3A is a cross-sectional illustration of an IMOD display element, where a strip of metal material is deposited on supports 18 extending generally orthogonally from the substrate 20 forming the movable reflective layer 14. In FIG. 3B, the movable reflective layer 14 of each IMOD display element is generally square or rectangular in shape and attached to supports at or near the corners, on tethers 32. In FIG. 3C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as implementations of “integrated” supports or support posts 18. The implementation shown in FIG. 3C has additional benefits deriving from the decoupling of the optical functions of the movable reflective layer 14 from its mechanical functions, the latter of which are carried out by the deformable layer 34. This decoupling allows the structural design and materials used for the movable reflective layer 14 and those used for the deformable layer 34 to be optimized independently of one another.

FIG. 3D is another cross-sectional illustration of an IMOD display element, where the movable reflective layer 14 includes a reflective sub-layer 14a. The movable reflective layer 14 rests on a support structure, such as support posts 18. The support posts 18 provide separation of the movable reflective layer 14 from the lower stationary electrode, which can be part of the optical stack 16 in the illustrated IMOD display element. For example, a gap 19 is formed between the movable reflective layer 14 and the optical stack 16, when the movable reflective layer 14 is in a relaxed position. The movable reflective layer 14 also can include a conductive layer 14c, which may be capable of serving as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, for example, an aluminum (Al) alloy with about 0.5% copper (Cu), or another reflective metallic material. Employing conductive layers 14a and 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 3D, some implementations also can include a black mask structure 23, or dark film layers. The black mask structure 23 can be formed in optically inactive regions (such as between display elements or under the support posts 18) to absorb ambient or stray light. The black mask structure 23 also can improve the optical properties of a display device by inhibiting light from being reflected from or transmitted through inactive portions of the display, thereby increasing the contrast ratio. Additionally, at least some portions of the black mask structure 23 can be conductive and be capable of functioning as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. In some implementations, the black mask structure 23 can be an etalon or interferometric stack structure. For example, in some implementations, the interferometric stack black mask structure 23 includes a molybdenum-chromium (MoCr) layer that serves as an optical absorber, an SiO₂ layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, tetrafluoromethane (or carbon tetrafluoride, CFO and/or oxygen (O₂) for the MoCr and SiO₂ layers and chlorine (Cl₂) and/or boron trichloride (BCl₃) for the aluminum alloy layer. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate electrodes (or conductors) in the optical stack 16 (such as the absorber layer 16a) from the conductive layers in the black mask structure 23.

FIG. 3E is another cross-sectional illustration of an IMOD display element, where the movable reflective layer 14 is self-supporting. While FIG. 3D illustrates support posts 18 that are structurally and/or materially distinct from the movable reflective layer 14, the implementation of FIG. 3E includes support posts that are integrated with the movable reflective layer 14. In such an implementation, the movable reflective layer 14 contacts the underlying optical stack 16 at multiple locations, and the curvature of the movable reflective layer 14 provides sufficient support that the movable reflective layer 14 returns to the unactuated position of FIG. 3E when the voltage across the IMOD display element is insufficient to cause actuation. In this way, the portion of the movable reflective layer 14 that curves or bends down to contact the substrate or optical stack 16 may be considered an “integrated” support post. One implementation of the optical stack 16, which may contain a plurality of several different layers, is shown here for clarity including an optical absorber 16a, and a dielectric 16b. In some implementations, the optical absorber 16a may serve both as a stationary electrode and as a partially reflective layer. In some implementations, the optical absorber 16a can be an order of magnitude thinner than the movable reflective layer 14. In some implementations, the optical absorber 16a is thinner than the reflective sub-layer 14a.

In implementations such as those shown in FIGS. 3A-3E, the IMOD display elements form a part of a direct-view device, in which images can be viewed from the front side of the transparent substrate 20, which in this example is the side opposite to that upon which the IMOD display elements are formed. In these implementations, the back portions of the device (that is, any portion of the display device behind the movable reflective layer 14, including, for example, the deformable layer 34 illustrated in FIG. 3C) can be configured and operated upon without impacting or negatively affecting the image quality of the display device, because the reflective layer 14 optically shields those portions of the device. For example, in some implementations a bus structure (not illustrated) can be included behind the movable reflective layer 14 that provides the ability to separate the optical properties of the modulator from the electromechanical properties of the modulator, such as voltage addressing and the movements that result from such addressing.

As used throughout, the terms “top,” “bottom,” “upper,” and “lower,” as used for ease of describing the Figures, indicate relative positions corresponding to the orientation on a properly oriented page, and may not reflect the proper orientation of the apparatus at hand. In some implementations, a top via may be the uppermost via in a stacked via structure, while in some implementations, there may be additional vias above the top via in a stacked via structure. Similarly, in some implementations, a bottom via may be the lowermost via structure, while in some implementations, there may be additional vias below the bottom via in a stacked via structure.

EMS devices and MEMS devices typically have many layers composed of different materials. Via structures can be built to route electrical signals vertically between layer structures. There may be challenges associated with building via structures that occupy a relatively small amount of space and that do not involve complicated processing of different materials.

Via structures that can be used for signal routing in multi-layer semiconductor, EMS, and MEMS devices include staggered vias, direct vias, and stacked vias. Staggered vias may include vias at different layers in a multi-layer device that are horizontally staggered or offset from each other. Because the vias are horizontally offset, staggered vias can occupy a large area in a multi-layer device. Direct vias can be fabricated by etching the multi-layer material from a top layer to a bottom layer to make an interconnection between layers. While a direct via may occupy a small area, fabrication processes for a direct via may be complicated when the via structure is formed in a multi-layer device with different materials in the layers. For example, the different materials in the different layers may etch at different rates, which may require precise process control, and may require different etchants. Stacked vias can constitute a plurality of metal layers in contact with one another at a central area of a via structure, and with dielectric layers between the metal layers at peripheral areas of the via structure. However, while the stacked via has a relatively good vertical interconnection and a relatively simple process control, the stacked via can introduce a high topography that can make later device integration more challenging.

An apparatus such as a display may include a pixel array that includes a number of pixel devices, such as EMS devices, including IMODs, and other components, such as matrixed active switches and drivers, as well as passive devices such as storage/sensing capacitors and resistors. The pixel devices and other components may include multi-layer structures with different materials in the layers. In operation of the apparatus, signals may be routed into and out of different layers of each pixel device.

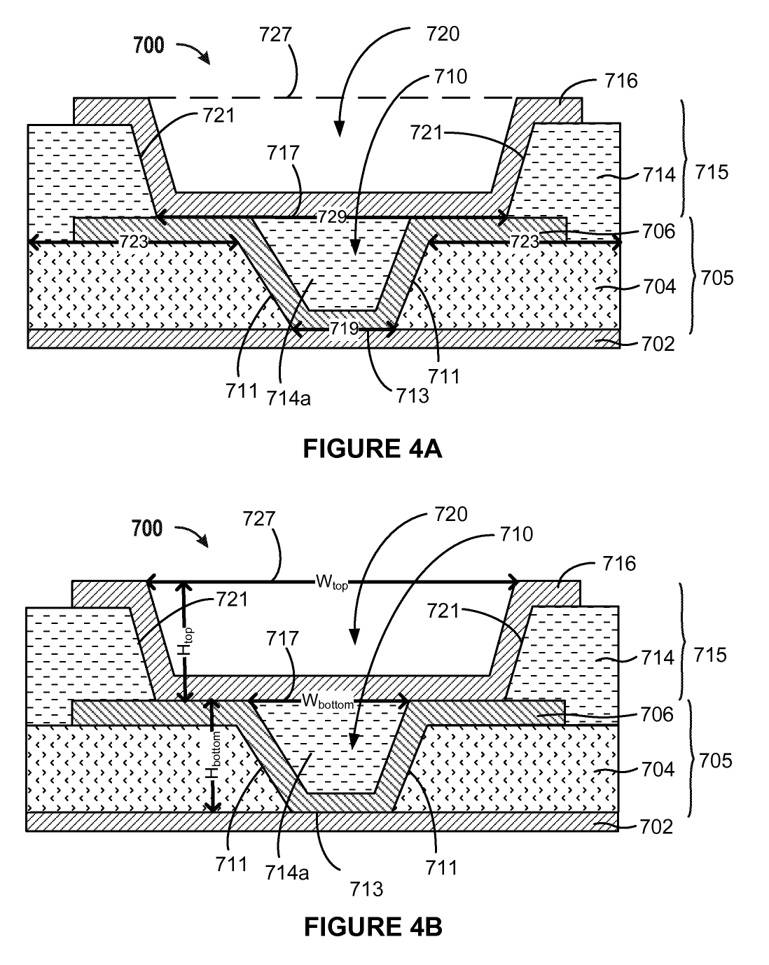

A unique stacked via structure described below with respect to FIGS. 4A-8C may be used for signal routing into and out of different layers of a multi-layer device. Also described are methods of fabrication the stacked via structures. In some implementations, the stacked via structures can be fabricated with relatively simple processing compared to fabrication of staggered and direct vias. In some implementations, the stacked via structure has a small form factor compared to staggered and direct vias and reduced topography compared to conventional stacked vias.

FIGS. 4A and 4B show an example of a cross-sectional schematic illustration of a stacked via structure. FIG. 4A shows the example of the stacked via structure identifying central and peripheral areas. FIG. 4B shows the example of the stacked via structure identifying widths and heights of a top via structure and a bottom via structure. In FIGS. 4A and 4B, the stacked via structure 700 includes a bottom via structure 705 and a top via structure 715 over the bottom via structure 705. The bottom via structure 705 includes a bottom dielectric layer 704 and a bottom via 710 extending through the bottom dielectric layer 704. The bottom via 710 includes a bottom metal 706 on the bottom dielectric layer 704 and along sidewalls 711 and a bottom plane 713 of the bottom via 710. As illustrated in FIG. 4A, the bottom via structure 705 includes a peripheral area 723 at which the bottom metal 706 overlies the bottom dielectric layer 704. The bottom via structure 705 also includes a central area 719 that is interior to the sidewalls 711 and to the peripheral area 723. The central area 719 can include an area extending from the bottom plane 713 of the bottom via 710 through a top plane 717 of the bottom via that is interior to the sidewalls 711. In some implementations, the central area 719 can include a part at which the bottom metal 706 makes electrical contact with a component other than the top via structure 715. In some implementations, as illustrated in the example in FIG. 4A, the central area 719 of the bottom metal 706 can contact a metal contact 702 at the bottom plane 713 of the bottom via 710. The metal contact 702 may be formed over a substrate (not shown). Examples of substrates are described throughout this disclosure.

The top via structure 715 includes a top dielectric layer 714 over the bottom metal 706 and over the bottom dielectric layer 704. In some implementations, the top dielectric layer 714 may substantially fill the bottom via 710 with dielectric material 714a. The top via structure 715 also includes a top via 720 that extends through the top dielectric layer 714 to a top plane 717 of the bottom via 710. In some implementations, the top plane 717 of the bottom via 710 may be the same as a bottom plane of the top via 720. The top via 720 further includes a top metal 716 formed on the top dielectric layer 714, along sidewalls 721 and on a top plane 717 of the bottom via 720. The top via structure 715 includes a central area 729 that is interior to the sidewalls 721. The central area 729 can include an area extending from the bottom plane 717 of the top via 720 to a top plane 727 of the top via 720 that is interior to the sidewalls 721. The top metal 716 is in electrical contact with the bottom metal 706 at the peripheral area 723 of the bottom via structure 705.

The top metal 716 and the bottom metal 706 may be made of different metals, including aluminum (Al), gold (Au), copper (Cu), molybdenum (Mo), tantalum (Ta), chromium (Cr), neodymium (Nd), tungsten (W), titanium (Ti), nickel (Ni), and an alloy including at least one of these metals. According to various implementations, the top metal 716 and the bottom metal 706 can be the same or different metals. In some implementations, the top metal 716 and the bottom metal 706 may each have a thickness of about 10 nm or less, about 100 nm or less, about 1000 nm or less, or about 5000 nm or less.

The dielectric of the top dielectric layer 714 and the bottom dielectric layer 704 may be any number of different dielectrics, including silicon dioxide (SiO₂), aluminum oxide (Al₂O₃), hafnium oxide (HfO₂), titanium oxide (TiO₂), tantalum oxide (TaO₂), silicon oxynitride (SiON), silicon nitride (SiN), spin-on-glass (such as organic or inorganic spin-on-glass (SOG)), or polymeric thin films such as polyimide (PI) and SU-8 epoxy photoresist. According to various implementations, the top dielectric layer 714 and the bottom dielectric layer 704 can be the same or different dielectric materials. In some implementations, the top dielectric layer 714 and the bottom dielectric layer 704 may each have a thickness of about 10 μm or less, about 5 μm or less, about 1 μm or less, or about 100 nm or less.

In some implementations, the width of each of the top via 720 and the bottom via 710 is between about 100 nm and about 5 μm. In some implementations, the depth of each of the top via 720 and the bottom via 710 is between about 100 nm and about 5 μm. In the stacked via structure 700 of FIGS. 4A and 4B, the top via structure 715 can be larger than the bottom via structure 705, with the top via 720 having a larger via size than the bottom via 710. For example, a width Wₜₒₚ of the top via 720 can be greater than a width W_{bottom} of the bottom via 710, or a diameter of a central portion of the top via 720 can be greater than a diameter of a central portion of the bottom via 710. The diameter or width W_{bottom} of the bottom via 710 can represent the distance across the sidewalls 711 at a top plane 717 of the bottom via 710. The diameter or width Wₜₒₚ of the top via 720 can represent the distance across the sidewalls 721 at a top plane 727 of the top via 720.

In some implementations, a depth-to-width aspect ratio of the top via 720 can be lower than an aspect ratio of the bottom via 710. The depth or height H_{bottom} of the bottom via 710 can extend from the top plane 717 of the bottom via 710 to the bottom plane 713 of the bottom via 710. The depth or height Hₜₒₚ of the top via 720 can extend from the top plane 727 of the top via 720 to the bottom plane 717 of the top via 720.

Central portions of the top metal 716 and the bottom metal 706 may be separated by dielectric material 714a. A central portion of the top metal 716 can refer to any portion interior to the sidewalls 721 and proximate the bottom plane 717 of the top via 720, and a central portion of the bottom metal 706 can refer to any portion interior to the sidewalls 711 and proximate the bottom plane 713 of the bottom via 710. The dielectric material 714a may substantially fill the bottom via 710. In the example of FIG. 4A, the dielectric material 714a in the bottom via 710 and that separates the top metal 716 and the bottom metal 706 is part of the top dielectric layer 714.

An electrical interconnection is made between the top via structure 715 and the bottom via structure 705 between the top metal 716 and the bottom metal 706 at peripheral area 723 of the stacked via structure 700. Instead of stacking one via structure over another via structure at the bottom surface of each via or in an central area 719 or central area 729 of each via, the stacked via structure 700 allows stacking one via structure over another so that metals overlap to form an electrical connection between a top surface of the bottom via 710 and a bottom surface of a top via 720 at the top plane 717 of the bottom via 710. This kind of stacking provides greater contact area for electrical interconnections and reduces topography in the overall device structure. In addition, the design of the stacked via structure 700 improves device integrity compared to other conventional stacked via structures.

In some implementations, the stacked via structure described earlier herein may be part of an EMS apparatus. This can include a display device having a pixel array and/or a thin film transistor (TFT) device. The stacked via structure may be electrically connected to one or more components of a display device. In some implementations, the metal contact in electrical contact with the stacked via structure described earlier herein may be in electrical communication with one or more of an EMS device and/or a TFT device.

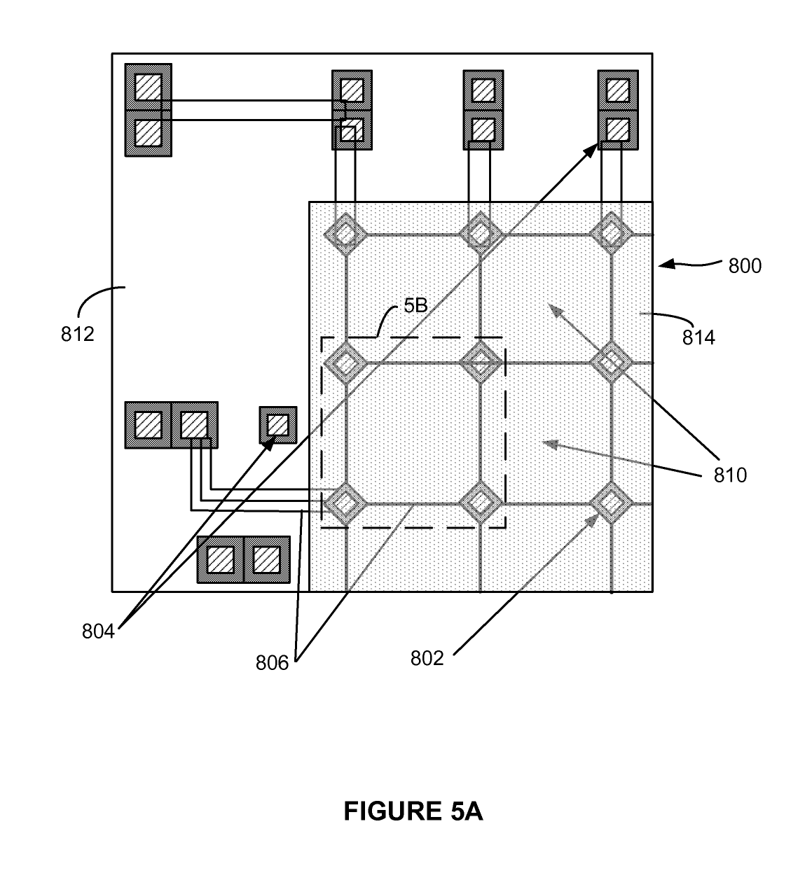

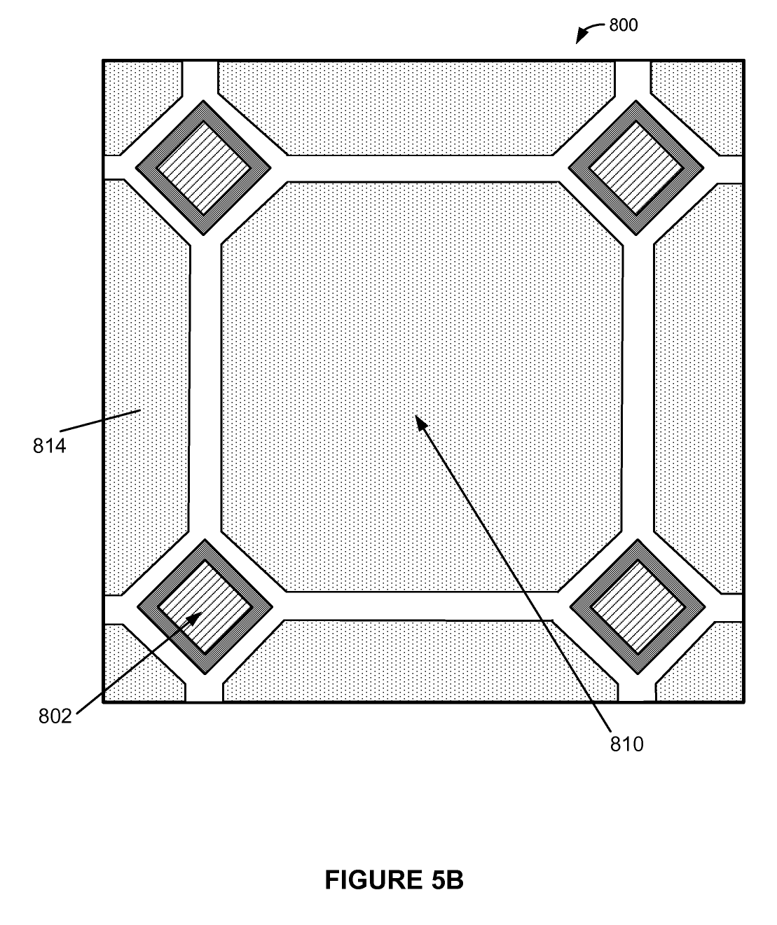

FIG. 5A shows an example of a top-down view of electrical interconnections in a display device. For ease of clarity, a person having ordinary skill in the art will appreciate that not all of the electrical interconnections in the display device are illustrated. In the example in FIG. 5A, the illustrated display device 800 may only be a portion of a display device, such as a flat panel display device. The display device 800 can include a peripheral region 812 and a pixel region 814, with the pixel region 814 including a plurality of pixels 810 in an array. Each of the pixels 810 can include EMS devices, such as IMODs, among other components. The display device 800 may further include via structures 802 and 804. Specifically, the display device 800 may include pixel region via structures 802 and peripheral region via structures 804. The via structures 802 and 804 may each occupy a small area and facilitate signal routing into and out of different layers of each pixel 810. As illustrated in the example in FIG. 5A, signal routing between various electrical components and via structures may occur through conductive traces 806.

FIG. 5B shows a magnified view of an example pixel region of the display device in FIG. 5A. Specifically, FIG. 5B shows a magnified detail view of the portion of the pixel region 814 enclosed in the dotted box labeled “5B” in FIG. 5A. The pixel region 814 of the display device 800 includes a pixel region via structure 802. It may be desirable for the pixel region via structure 802 to be relatively small so as to occupy as little space as possible in the pixel region. In some implementations, the pixel region via structure 802 occupies an area of less than about 6 μm×6 μm, less than about 3 μm×3 μm, or less than about 0.5 μm×0.5 μm hole in diameter.

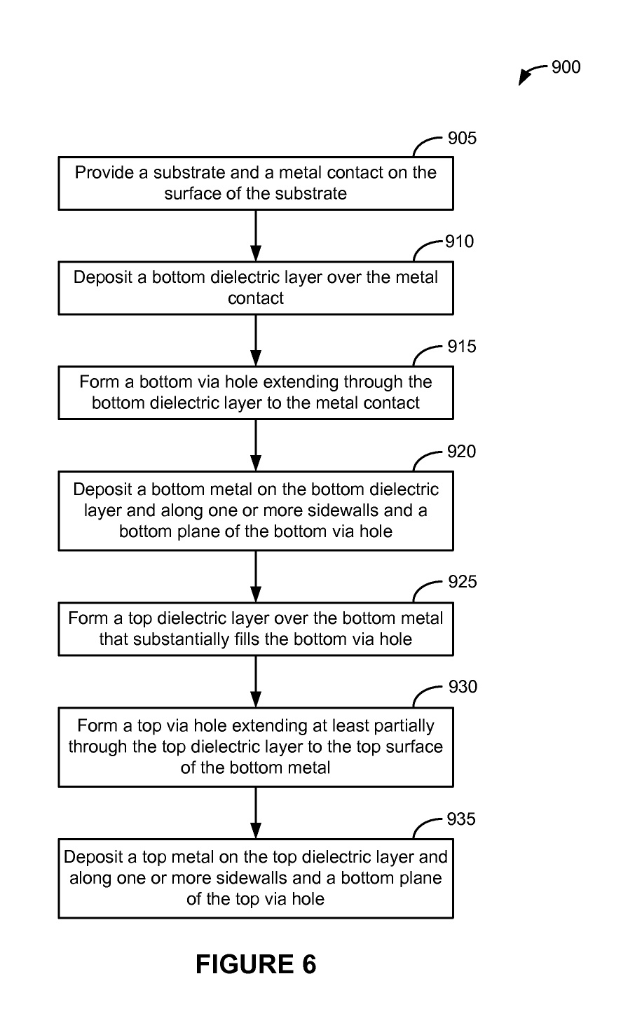

Formation of the pixel region via structure 802 may involve etching through multiple layers in the pixel region 814 of the display device 800. In some implementations, layers can include but are not limited to mechanical layers, buffer layers, dielectric layers, reflective layers, absorber layers, metal layers, bussing layers, black mask layers, and the like. For example, in one implementation, about 2 μm of SiO₂ or tetraethyl orthosilicate (TEOS) may be etched, followed by about 220 Å of TiO₂, and then followed by about 770 Å of SiON. The etch process may cease at a 500 Å layer of AlCu. Of course, it is understood that any suitable number and types of layers, materials, and thicknesses may be etched according to a desired specification. The pixel region via structure 802 may be a via structure such as shown in FIG. 4A and may be formed according to a process described in more detail below with reference to FIGS. 6-8C. As discussed earlier herein, signal routing may occur going into and out from any of the aforementioned layers.

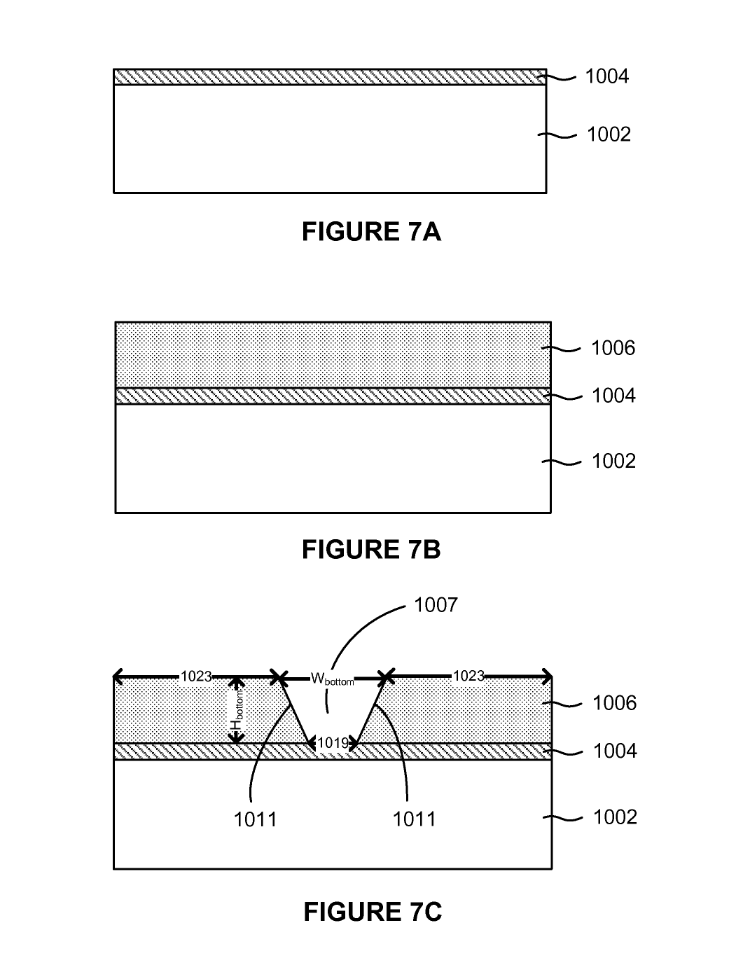

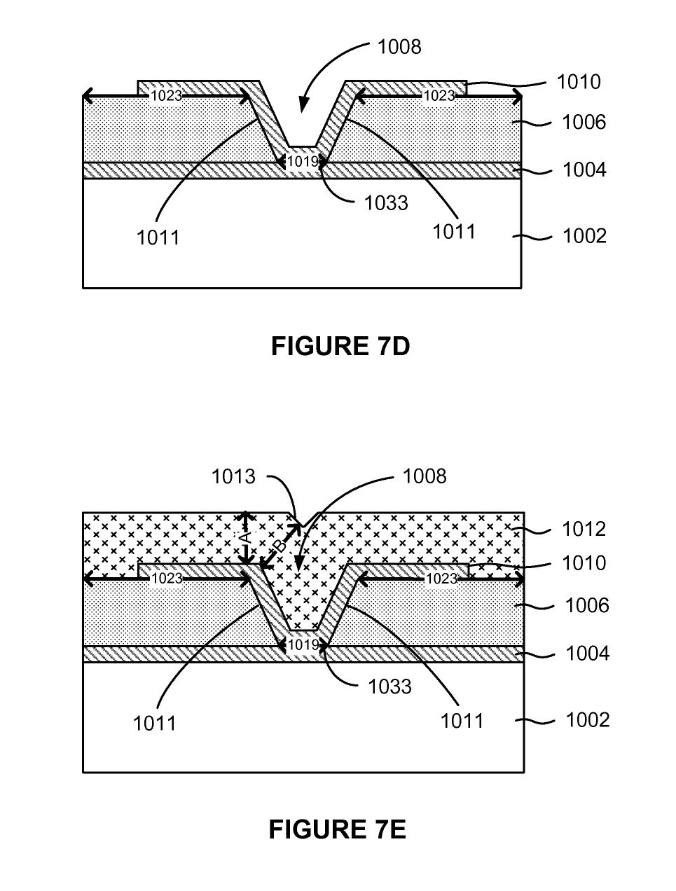

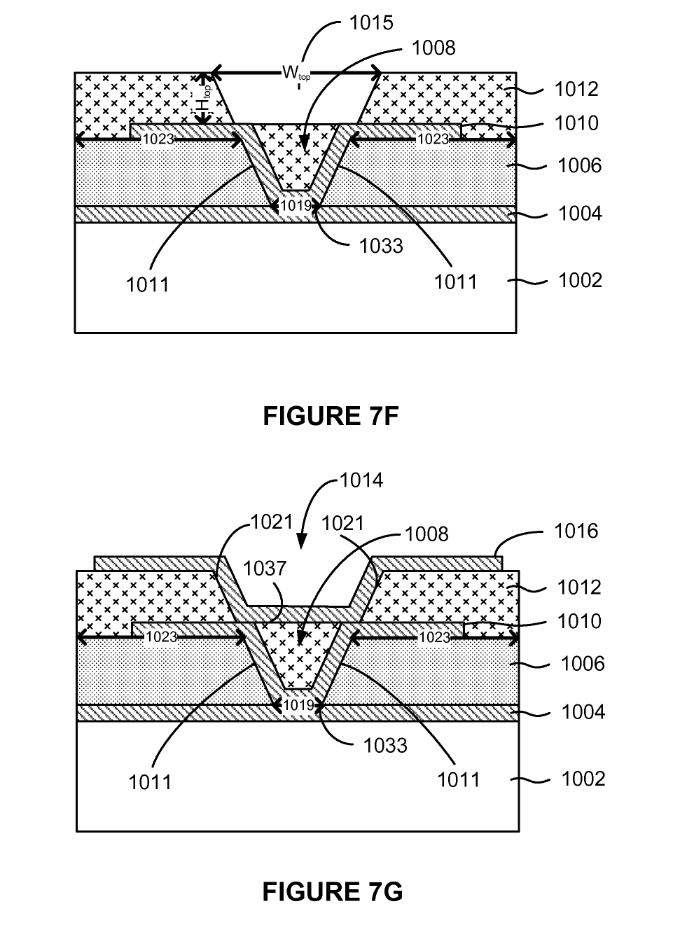

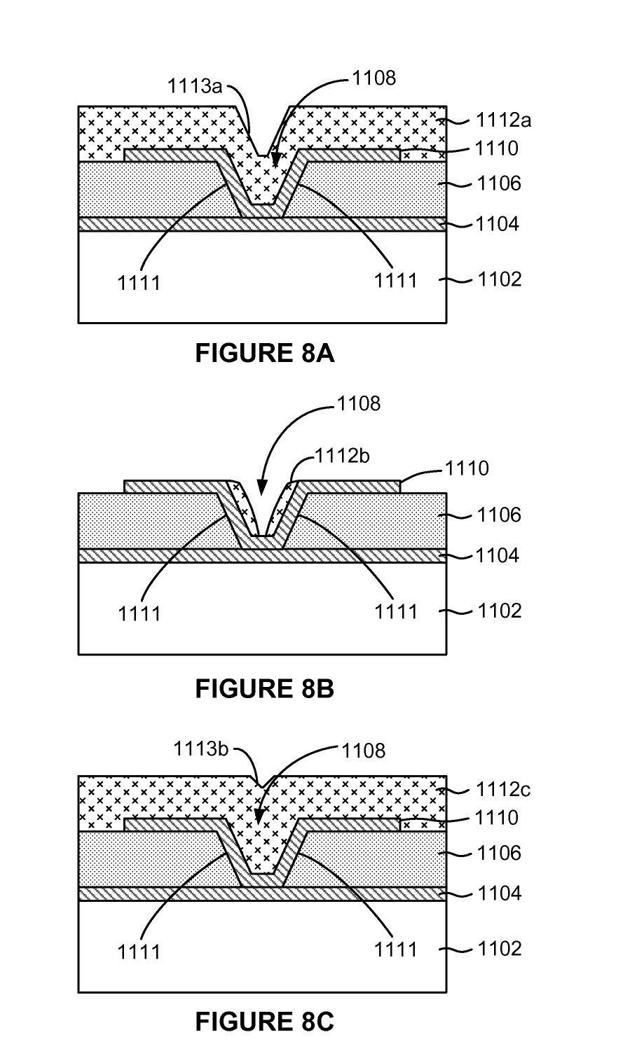

Implementations of manufacturing a stacked via structure may be set forth below with respect to FIGS. 6, 7A-7G and 8A-8C. FIG. 6 shows a flow diagram illustrating an example method of manufacturing a stacked via structure. A person having ordinary skill in the art will readily understand that additional stages not shown in FIG. 6 also may be present. FIGS. 7A-7G show cross-sectional example schematic illustrations of various stages of manufacturing a stacked via structure. FIGS. 8A-8C show cross-sectional example schematic illustrations of various stages of forming a top dielectric layer with a hole in FIG. 7E. In some implementations, the stacked via structure can be part of a manufacturing process of any EMS device, MEMS device, or semiconductor device, especially any semiconductor device with chip level interconnects.

At block 905 of the process 900, a substrate and a metal contact on the surface of the substrate are provided. The substrate can include a semiconductor or insulating material. The substrate may be made of any number of different substrate materials, including transparent and non-transparent materials. In some implementations, the substrate may be part of an integrated circuit with one or more active or passive devices formed thereon. The metal contact may be formed using any suitable deposition technique, such as PVD, CVD, ALD, and electroplating. In some implementations, the metal contact also may be patterned using any suitable patterning technique, such as photolithography.

FIG. 7A shows an example of a cross-sectional schematic side view of a partially fabricated apparatus (see block 905) in the process 900. A metal contact 1004 may be formed on the surface of the substrate 1002. The metal contact 1004 may include any number of different metals, such as aluminum (Al), gold (Au), copper (Cu), molybdenum (Mo), tantalum (Ta), chromium (Cr), neodymium (Nd), tungsten (W), titanium (Ti), nickel (Ni), and alloys thereof, such as MoCr, AlCu, and AlSi. In some implementations, the metal contact 1004 may be less than about 10 nm thick, tens of nanometers thick, hundreds of nanometers thick, or microns thick.

The substrate 1002 may include different substrate materials, including transparent materials, non-transparent materials, flexible materials, rigid materials, or combinations thereof. For example, the substrate 1002 can include silicon (Si), silicon-on-insulator (SOI), germanium (Ge), silicon germanium (SiGe), gallium arsenide (GaAs), gallium arsenide phosphide (GaAsP), indium phosphide (InP), gallium aluminum arsenic (GaAlAs), indium gallium phosphide (InGaP), silicon carbide (SiC), SiO₂, glass, and quartz. In some implementations, the substrate 1002 can have dimensions of a few microns to hundreds of microns. For example, the substrate 1002 can have a thickness between about 10 μm and about 1100 μm. In some implementations, the substrate 1002 can have dimensions of about tens, hundreds, or thousands of centimeters.

The substrate 1002 can include any number of layers of different materials. For example, a glass substrate or Si substrate may include one or more layers formed on the glass or Si surface. In some implementations, the substrate 1002 can include a buffer layer, which can serve as an insulation surface or passivation layer to seal a surface of the substrate 1002. The buffer layer can include a dielectric, which can be a glass material with high resistivity. This can include fused silica, quartz, SiO₂, or silicate. The dielectric also can include silicon nitrides, silicon carbides, silicon oxynitrides, ceramics, glass ceramics, plastics, polymers, epoxies, and the like. The buffer layer also may be any multi-layered combination of these materials. In some implementations, the buffer layer may be about 100 nm to about 10 μm in thickness, such as about 1 μm in thickness.

The substrate 1002 may have regions extending to portions where other devices or components other than via structures may be formed over the substrate 1002. In particular, one or more devices (not shown), such as semiconductor devices, EMS devices, and/or conductive traces may be formed over the substrate 1002.

At block 910 of the process 900, a bottom dielectric layer is deposited over the metal contact. The bottom dielectric layer may be deposited using any suitable deposition technique known in the art, such as PVD, thermal CVD, PECVD, or ALD.

FIG. 7B shows an example of a cross-sectional schematic side view of a partially fabricated apparatus (see block 910) in the process 900. A bottom dielectric layer 1006 is formed over the metal contact 1004 and the substrate 1002. The dielectric of the bottom dielectric layer 1006 may include any number of different dielectrics, such as SiO₂, SiC, Al₂O₃, HfO₂, TiO₂, SiON, silicon nitride (SiₓN), spin-on-glass (organic or inorganic SOG), or polymeric materials such as polyimide, BCB, SU-8. In some implementations, the bottom dielectric layer 1006 may be less than about 5 μm thick, or less than about 1 μm thick. For example, the bottom dielectric layer 1006 may be about 2 μm thick.

At block 915 of the process 900, a bottom via hole extending through the bottom dielectric layer to the metal contact is formed. Any suitable patterning technique, such as lithography and/or etching process, may be used to form the bottom via hole. This can include wet etching or dry etching, including plasma etching, reactive ion etching, and ion beam milling. Other processes can include a laser ablation process, a mediablasting or sandblasting process, an ultrasonic drilling process, and photo processes. According to various implementations, the etching process can be capable of creating a bottom via hole having one of various profiles. For example, the bottom via hole may have substantially vertical sidewalls or a tapered profile with sloped sidewalls.

FIG. 7C shows an example of a cross-sectional schematic side view of a partially fabricated apparatus (see block 915) in the process 900. The apparatus includes the substrate 1002, the metal contact 1004, the bottom dielectric layer 1006, and a bottom via hole 1007. The bottom dielectric layer 1006 does not overlie a central portion 1019 of the apparatus, but does overlie peripheral portions 1023.

As shown in the example of FIG. 7C, the bottom via hole 1007 may extend through the bottom dielectric layer 1006 to expose a portion of the metal contact 1004. The bottom via hole 1007 may be formed using an etching process to anisotropically remove the bottom dielectric layer 1006 to expose the metal contact 1004. In some implementations, the etching process can include plasma etchants such as tetrafluoromethane (CF₄). In the example of FIG. 7C, the bottom via hole 1007 has a tapered profile along sidewalls 1011. A tapered profile along the sidewalls 1011 of the bottom via hole 1007 can improve step coverage issues for subsequent deposition processes. In the alternative, or in addition, the etching process and lithography process can be capable of reducing the size of the central diameter of the bottom via hole 1007 and/or create more taper to further improve step coverage. In some implementations, a central diameter or width W_{bottom} of the bottom via hole 1007 can be between about 0.1 μm and about 10 μm, and the depth or height H_{bottom} of the bottom via hole 1007 can be between about 0.1 μm and about 10 μm.

In some implementations, the etching process can etch through multiple layers by using different chemistries for different materials, including the bottom dielectric layer 1006, to expose the metal contact 1004. As discussed earlier herein, the etching process may etch through a layer of Al₂O₃ at a peripheral region of a display device. In some implementations, the etching process can etch to the metal contact 1004 using endpoint controls in an optical emission spectrum. The etching process can switch to a timed etch to etch through one or more layers, such as a layer of Al₂O₃.

At block 920 of the process 900, a bottom metal is deposited on the bottom dielectric layer and along one or more sidewalls and the bottom plane of the bottom via hole. The bottom metal is deposited using any suitable deposition technique known in the art, such as PVD, CVD, ALD, and electroplating. The bottom metal may be conformally and continuously deposited along the surface of the bottom dielectric layer and the exposed metal contact, as well as along the sloped or vertical sidewalls of the bottom via hole. In some implementations, the bottom metal is also etched at this point to pattern the bottom metal prior to subsequent deposition of materials. Patterning the bottom metal prior to subsequent deposition processes may reduce the likelihood of the formation of “stringers,” which are unwanted metal residue in the valley of high topography areas that can lead to shorting between two or more isolated metal nodes. Stringer formation can occur if the metal is protected by subsequently deposited material along the sidewall prior to patterning the bottom metal. In some other implementations, the bottom metal is not etched and patterned.

FIG. 7D shows an example of a cross-sectional schematic side view of a partially fabricated apparatus (see block 920) in the process 900. The apparatus includes the substrate 1002, the metal contact 1004, the bottom dielectric layer 1006, and a bottom via 1008 that includes a bottom metal 1010. The bottom metal 1010 may be in contact with the exposed portion of the metal contact 1004. The bottom metal 1010 may be the same metal or a different metal as the metal contact 1004. In some implementations, the bottom metal 1010 may be about the same thickness as the metal contact 1004, and in some implementations, the bottom metal 1010 may be a different thickness than the metal contact 1004.

The bottom metal 1010 may be deposited over the bottom dielectric layer 1006 and the metal contact 1004 so that the bottom metal 1010 contacts the metal contact 1004 at the central portion 1019 of the apparatus, and the bottom metal 1010 contacts the bottom dielectric layer 1006 at the peripheral portions 1023 of the apparatus. In some implementations, the bottom metal 1010 may be patterned so that the bottom metal 1010 partially overlies the peripheral portions 1023 of the apparatus. The bottom metal 1010 may be conformal along the sidewalls 1011 of the bottom via 1008 and along a bottom plane 1033 of the bottom via 1008. Because the sidewalls 1011 of the bottom via 1008 may have a vertical or sloped profile, the bottom metal 1010 may follow an identical or similar profile. In the example of FIG. 7D, the bottom metal 1010 may be substantially planar along the bottom dielectric layer 1006, angled along the sidewalls 1011 of the bottom via 1008, and substantially planar along the exposed portion of the metal contact 1004. In some implementations, the angled portions of the bottom metal 1010 may form an angle between about 90 degrees and about 150 degrees with the substantially planar portions of the bottom metal 1010.

At block 925 of the process 900, a top dielectric layer is formed over the bottom metal that substantially fills the bottom via hole. The formation of the top dielectric layer may involve one or more processing steps, including deposition and etching steps. In some implementations, the top dielectric layer may be deposited, etched, and re-deposited to achieve a desired step coverage over the bottom metal. A sequence of deposition and etching steps may be repeated. In some implementations, the top dielectric layer may be deposited using a highly conformal deposition process.

FIG. 7E shows an example of a cross-sectional schematic side view of a partially fabricated apparatus (see block 925) in the process 900. The apparatus includes the substrate 1002, the metal contact 1004, the bottom dielectric layer 1006, the bottom via 1008 including the bottom metal 1010, and a top dielectric layer 1012. In some implementations, the top dielectric layer 1012 may include the same or different dielectric as the bottom dielectric layer 1006. In some implementations, the top dielectric layer 1012 may be the same thickness as the bottom dielectric layer 1006, and in some implementations, the top dielectric layer 1012 may be a different thickness than the bottom dielectric layer 1006. The top dielectric layer 1012 at least substantially fills the bottom via 1008.

The top dielectric layer 1012 is formed in FIG. 7E having a hole 1013 at the top surface of the top dielectric layer 1012. The hole 1013 also may be referred to as a pinch, gap, notch, keyhole, cavity, or opening. The size and shape of the hole 1013 may depend on a variety of factors, including but not limited to via depth-width ratio, the thickness of the top dielectric layer 1012, the etch conditions in forming the bottom via 1008, and the deposition conditions in forming the top dielectric layer 1012. For example, the deposition conditions in forming the dielectric layer 1012 may be capable of improving the step coverage over the bottom metal 1010. The step coverage may be represented as a ratio between a thickness (B) of the top dielectric layer 1012 along the sidewalls 1011 of the bottom via 1008 against a thickness (A) of the top dielectric layer 1012 along the bottom metal 1010 at the peripheral portions 1023 of the apparatus. A higher step coverage ratio (B/A) may be desirable to reduce the size of the hole 1013. An alternative process for improving the step coverage ratio is discussed in further detail below with respect to FIGS. 8A-8C.

FIGS. 8A-8C show examples of cross-sectional schematic illustrations of various stages of forming a top dielectric layer with a hole in FIG. 7E. A person having ordinary skill in the art will readily understand that FIGS. 8A-8C illustrate one among many processes of forming a top dielectric with a hole in FIG. 7E. The processing stages shown in FIGS. 8A-8C may include a sequence of deposition, etching, and deposition. Additionally, a person having ordinary skill in the art will readily understand that additional stages also may be present in FIGS. 8A-8C.

In FIG. 8A, an apparatus includes a substrate 1102, a metal contact 1104, a bottom dielectric layer 1106, and a bottom via 1108 including a bottom metal 1110. A first top dielectric layer 1112a is deposited over the bottom metal 1110 that at least partially fills the bottom via 1108. The first top dielectric layer 1112a may be deposited using any suitable deposition technique known in the art, such as PVD, CVD, ALD, coating and laminating organic materials. When the first top dielectric layer 1112a is deposited, the deposition conditions may produce a large hole 1113a at a top surface of the first top dielectric layer 1112a. The large hole 1113a may extend towards the bottom via 1108. In fact, in some implementations, the large hole 1113a may even protrude past the top plane of the bottom via 1108.

In FIG. 8B, the first top dielectric layer 1112a is etched in a manner so as to leave dielectric or sidewall spacers 1112b in the bottom via 1108. By applying a certain type of etch, such as a blank etch, and certain etch conditions, the first top dielectric layer 1112a may be etched away while leaving some dielectric material on the sidewalls 1111 of the bottom via 1108. In some implementations, the etch conditions may include relatively non-aggressive plasma etch conditions. The non-aggressive plasma etch conditions may include a reduced power, increased pressure, absence of argon (Ar), and/or an earlier endpoint in an optical emission spectrum compared to typical plasma etch conditions for effectively removing a dielectric layer. The non-aggressive plasma etch conditions provide sidewall spacers 1112b formed on portions of the bottom metal 1110 to be left behind from the first top dielectric layer 1112a. The sidewall spacers 1112b provide a smaller central diameter for the bottom via 1108 and a greater amount of taper in the bottom via 1108. In some implementations, the first top dielectric layer 1112a may be substantially etched away, and then sidewall spacers 1112b may be subsequently formed on the sidewalls 1111 of the bottom via 1108.

In FIG. 8C, a second top dielectric layer 1112c is deposited over the bottom metal 1110 and over the sidewall spacers 1112b that substantially fills the bottom via 1108. The deposition of the second top dielectric layer 1112c leaves a small hole 1113b at the top surface of the second top dielectric layer 1112c. The small hole 1113b does not protrude beyond the top plane of the bottom via 1108. The second top dielectric layer 1112c may be deposited using any suitable deposition technique known the art, such as PVD, CVD, ALD, coating, and laminating organic materials.

Returning to FIG. 6, the process 900 may further include etching at least partially the top dielectric layer after depositing the top dielectric layer over the bottom metal. Furthermore, the process 900 may further include re-depositing the top dielectric layer over the bottom metal that substantially refills the bottom via hole. In some implementations, etching at least partially the top dielectric layer includes etching only partially the top dielectric layer to provide one or more dielectric spacers along one or more sidewalls of the bottom via.

Returning to FIGS. 6 and 7A-7G, at block 930 of the process 900, a top via hole is formed extending at least partially through the top dielectric layer to the top surface of the bottom metal. Any suitable patterning technique may be used to form the top via hole, including plasma etching. Etch conditions can be controlled so that etching through the top dielectric layer does not extend beyond the bottom metal.

FIG. 7F shows an example of a cross-sectional schematic side view of a partially fabricated apparatus see block 930) in the process 900. The apparatus includes the substrate 1002, the metal contact 1004, the bottom dielectric layer 1006, the bottom via 1008 including the bottom metal 1010, the top dielectric layer 1012, and a top via hole 1015. The top dielectric layer 1012 overlies a part of the peripheral portions 1023 over the bottom metal 1010 and overlies the central portion 1019 over the bottom metal 1010. The top dielectric layer 1012 substantially fills the bottom via 1008. In some implementations, the top surface of the top dielectric layer 1012 in the bottom via 1008 is substantially planar.

In some implementations, the etching process to form the top via hole 1015 can be capable of creating a tapered profile along the sidewalls of the top via hole 1015. A central diameter of the top via hole 1015 may be wider than a central diameter of the bottom via hole 1007. In some implementations, a central diameter or width Wₜₒₚ of the top via hole 1015 can be between about 0.1 μm and about 5 μm, between about 5 μm and about 10 μm, or greater than about 10 μm, and a depth or height Hₜₒₚ of the top via hole 1015 can be between about 0.1 μm and about 5 μm, between about 5 μm and about 10 μm, or greater than about 10 μm.

The etching process may etch up to the bottom metal 1010. In some implementations, this can be achieved using endpoint controls in an optical emission spectrum. Due at least in part to the hole 1013 in FIG. 7E, etching through the top dielectric layer 1012 and beyond the top plane of the bottom via 1008 may be minimized. Instead of etching into the top dielectric layer 1012 in the bottom via 1008, the top dielectric layer 1012 in the bottom via 1008 remains relatively planar for subsequent deposition. This can reduce the likelihood of unwanted topography.

At block 935 of the process 900, a top metal is deposited on the top dielectric layer and along one or more sidewalls and a bottom plane of the top via hole. The top metal is deposited using any suitable deposition technique known in the art. The top metal may be conformally and continuously deposited along the surface of the top dielectric layer and the exposed bottom metal, as well as along the sloped or vertical sidewalls of the top via hole. In some implementations, the top metal is also patterned.

FIG. 7G shows an example of a cross-sectional schematic side view of an apparatus (see block 935) in the process 900. The apparatus includes the substrate 1002, the metal contact 1004, the bottom dielectric layer 1006, the bottom via 1008 that includes the bottom metal 1010, the top dielectric layer 1012, and a top via 1014 that includes a top metal 1016. The top metal 1016 may be in contact with the exposed portion of the bottom metal 1010. The contact with the bottom metal 1010 is made at peripheral portions 1023 of the apparatus. In some implementations, the top metal 1016 may be the same metal as the bottom metal 1010, and in some implementations, the top metal 1016 may be a different metal from the bottom metal 1010. In some implementations, the top metal 1016 may be about the same thickness as the bottom metal 1010, and in some implementations, the top metal 1016 may be a different thickness than the bottom metal 1010.

The top metal 1016 may be deposited over the top dielectric layer 1012 and the bottom metal 1010 so that the top metal 1016 contacts the bottom metal 1010 at peripheral portions 1023 of the apparatus and the top metal 1016 contacts the top dielectric layer 1012 in the bottom via 1008 at a central portion 1019 of the apparatus. In some implementations, the top metal 1016 may be patterned so that the top metal 1016 partially overlies the top dielectric layer 1012 in the peripheral portions 1023 of the apparatus. The top metal 1016 may be conformal along the sidewalls 1021 of the top via 1014 and along the top plane 1037 of the bottom via 1008. The top metal 1016 may be substantially planar along the top dielectric layer 1012, and angled along the sidewalls 1021 of the top via 1014. In some implementations, the angled portions of the top metal 1016 may form an angle between about 90 degrees and about 150 degrees with the substantially planar portions of the top metal 1016. By having the top metal 1016 conformally and continuously deposited in the top via 1014, especially in a top via 1014 having a relatively shallow aspect ratio, the completed apparatus in FIG. 7G can have greater device integrity.

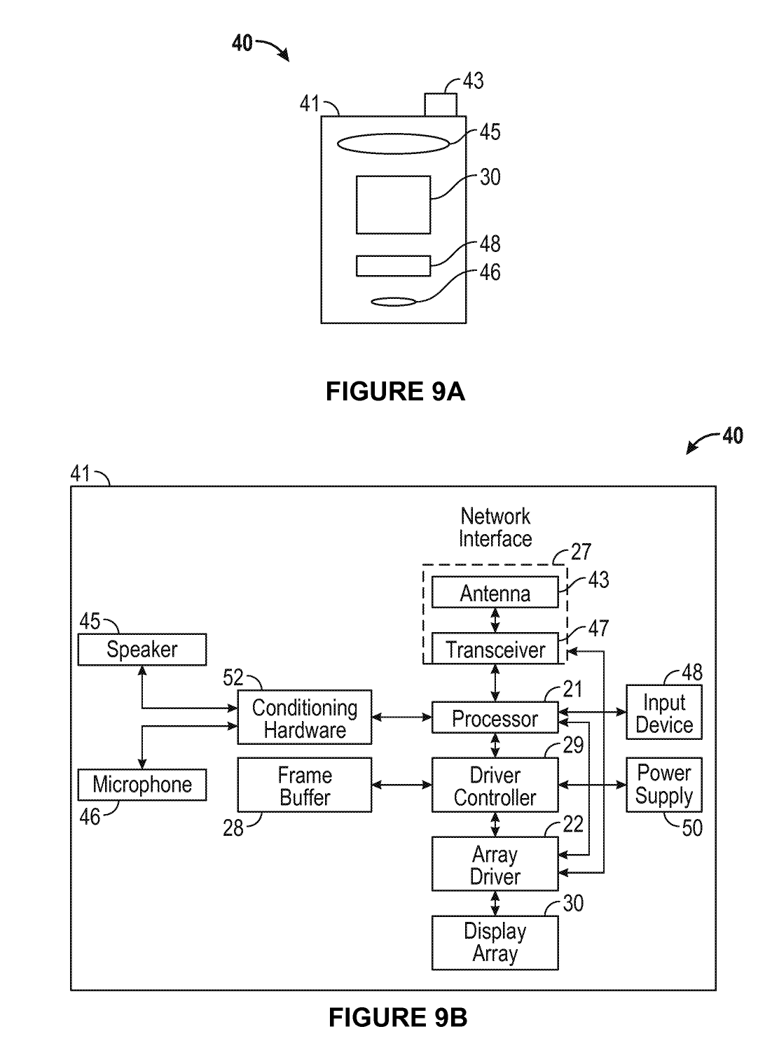

FIGS. 9A and 9B are system block diagrams illustrating a display device 40 that includes a plurality of IMOD display elements. The display device 40 can be, for example, a smart phone, a cellular or mobile telephone. However, the same components of the display device 40 or slight variations thereof are also illustrative of various types of display devices such as televisions, computers, tablets, e-readers, hand-held devices and portable media devices.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an IMOD-based display, as described herein.

The components of the display device 40 are schematically illustrated in FIG. 9A. The display device 40 includes a housing 41 and can include additional components at least partially enclosed therein. For example, the display device 40 includes a network interface 27 that includes an antenna 43 which can be coupled to a transceiver 47. The network interface 27 may be a source for image data that could be displayed on the display device 40. Accordingly, the network interface 27 is one example of an image source module, but the processor 21 and the input device 48 also may serve as an image source module. The transceiver 47 is connected to a processor 21, which is connected to conditioning hardware 52. The conditioning hardware 52 may be capable of conditioning a signal (such as filter or otherwise manipulate a signal). The conditioning hardware 52 can be connected to a speaker 45 and a microphone 46. The processor 21 also can be connected to an input device 48 and a driver controller 29. The driver controller 29 can be coupled to a frame buffer 28, and to an array driver 22, which in turn can be coupled to a display array 30. One or more elements in the display device 40, including elements not specifically depicted in FIG. 9A or 9B, can be capable of functioning as a memory device and be capable of communicating with the processor 21. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the Bluetooth® standard. In the case of a cellular telephone, the antenna 43 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that can be readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of display elements.

In some implementations, the driver controller 29, the array driver 22, and the display array 30 are appropriate for any of the types of displays described herein. For example, the driver controller 29 can be a conventional display controller or a bi-stable display controller (such as an IMOD display element controller). Additionally, the array driver 22 can be a conventional driver or a bi-stable display driver (such as an IMOD display element driver). Moreover, the display array 30 can be a conventional display array or a bi-stable display array (such as a display including an array of IMOD display elements). In some implementations, the driver controller 29 can be integrated with the array driver 22. Such an implementation can be useful in highly integrated systems, for example, mobile phones, portable-electronic devices, watches or small-area displays.

In some implementations, the input device 48 can be capable of allowing, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be capable of receiving power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of, e.g., an IMOD display element as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An apparatus comprising:
a bottom via structure including:
a bottom dielectric layer; and
a bottom via extending through the bottom dielectric layer and including a bottom metal formed on the bottom dielectric layer and along one or more sidewalls and a bottom plane of the bottom via, wherein the bottom via is substantially filled by a dielectric material; and
a top via structure over the bottom via structure, including:
a top dielectric layer over the bottom metal; and
a top via extending to a top plane of the bottom via in the top dielectric layer and including a top metal formed on the top dielectric layer and along one or more sidewalls and a bottom plane of the top via, wherein the top metal is in electrical contact with the bottom metal at a peripheral area of the bottom via structure.

2. The apparatus of claim 1, wherein a width of the top via is greater than a width of the bottom via.

3. The apparatus of claim 1, wherein central portions of the top and bottom metals are separated by the dielectric material.

4. The apparatus of claim 1, wherein a part of the dielectric material is a part of the top dielectric layer.

5. The apparatus of claim 1, wherein at least one of a depth or a width of each of the top via and the bottom via is between about 0.1 μm and about 10 μm.

6. The apparatus of claim 1, wherein the apparatus is part of an electromechanical systems (EMS) apparatus.

7. The apparatus of claim 6, wherein the EMS apparatus is part of a pixel array.

8. The apparatus of claim 1, further including a metal contact in electrical communication with the bottom metal, and wherein the metal contact is in electrical communication with one or more of an EMS device and a thin film transistor (TFT) device.

9. The apparatus of claim 1, wherein at least one of the top metal and the bottom metal includes at least one material selected from the group consisting of: aluminum (Al), copper (Cu), gold (Au), molybdenum (Mo), tantalum (Ta), chromium (Cr), neodymium (Nd), tungsten (W), titanium (Ti), and nickel (Ni).

10. The apparatus of claim 1, wherein at least one of the top and the bottom dielectric layer includes at least one material selected from the group consisting of: a silicon oxide, an aluminum oxide, a hafnium oxide, a titanium oxide, a silicon oxynitride, a silicon nitride, a silicon carbide, a zirconium oxide, a tantalum oxide, spin-on glass, and a polymer material.

11. The apparatus of claim 1, wherein the bottom plane of the top via is substantially co-planar with the top plane of the bottom via.

12. The apparatus of claim 1, further comprising:
a display;
a processor that is configured to communicate with the display, the processor being configured to process image data; and
a memory device that is configured to communicate with the processor.

13. A method, comprising:
providing a substrate and a metal contact on the surface of the substrate;
depositing a bottom dielectric layer over the metal contact;
forming a bottom via hole extending through the bottom dielectric layer to the metal contact;
depositing a bottom metal on the bottom dielectric layer and along one or more sidewalls and the bottom plane of the bottom via hole;
forming a top dielectric layer over the bottom metal that substantially fills the bottom via hole;
forming a top via hole extending at least partially through the top dielectric layer to the top surface of the bottom metal; and
depositing a top metal on the top dielectric layer and along one or more sidewalls and a bottom plane of the top via hole.

14. The method of claim 13, further comprising:
etching at least partially the top dielectric layer after depositing the top dielectric layer over the bottom metal; and
re-depositing the top dielectric layer over the bottom metal that substantially re-fills the bottom via hole.

15. The method of claim 14, wherein etching at least partially the top dielectric layer includes etching only partially the top dielectric layer to provide one or more dielectric spacers along the one or more sidewalls of the bottom via hole.

16. The method of claim 14, further comprising:
etching the bottom metal on the bottom dielectric layer to pattern the bottom metal.

17. The method of claim 16, wherein etching the bottom metal occurs before depositing the top dielectric layer over the bottom metal.

18. The method of claim 13, wherein depositing the top metal includes forming an electrical contact with the bottom metal at a peripheral area of the bottom metal.

19. The method of claim 13, wherein a width of the top via hole is greater than a width of the bottom via hole.

20. An apparatus comprising:
a metal contact;
a bottom via structure over the metal contact, including:
a bottom dielectric layer; and
a bottom via extending through the bottom dielectric layer and including a bottom metal formed on the bottom dielectric layer and along one or more sidewalls and a bottom plane of the bottom via, wherein the bottom metal is in electrical contact with the metal contact; and
a top via structure over the bottom via structure, including:
a top dielectric layer over the bottom metal, wherein the top dielectric layer substantially fills the bottom via; and
a top via extending to a top plane of the bottom via in the top dielectric layer and including a top metal formed on the top dielectric layer and along one or more sidewalls and a bottom plane of the top via, wherein the top metal is in electrical contact with the bottom metal at a peripheral area of the bottom via structure, wherein a width of the top via is greater than a width of the bottom via, and wherein central portions of the top and bottom metals are separated by the top dielectric layer.
